(19) United States
(12) Patent Application Publication
(10) Pub. No.: US 2025/0133685 A1
(43) Pub. Date: Apr. 24, 2025

(54) ELECTRONIC DEVICE, SPLICE ELECTRONIC APPARATUS AND MANUFACTURING METHOD OF ELECTRONIC DEVICE

(71) Applicant: InnoLux Corporation, Miao-Li County (TW)

(72) Inventors: Hung-Ming HSIEH, Miao-Li County (TW); Tzu-Yuan LIN, Miao-Li County (TW)

(21) Appl. No.: 18/829,570

(22) Filed: Sep. 10, 2024

(30) Foreign Application Priority Data
Oct. 20, 2023 (CN) 202311367876.5

(51) Int. Cl. H05K 7/18; G09F 9/302; H05K 5/02; H05K 7/14; H05K 11/00; H05K 13/00

(52) U.S. Cl. CPC H05K 7/18; G09F 9/3023; H05K 5/0204; H05K 7/1452; H05K 13/0015; H05K 11/00

(57) ABSTRACT

An electronic device is provided, including an electronic panel, a reinforcement plate, and at least three adjustment members. The reinforcement plate has a first surface and a second surface that are opposite to each other. The electronic panel is disposed on the first surface of the reinforcement plate, and the adjustment members are disposed on the second surface. The electronic panel has an upper surface. There is a distance between a bottom surface of each adjustment member and the upper surface. The difference between the distances is greater than or equal to 0 and less than or equal to 0.1 millimeters.

### CROSS REFERENCE TO RELATED APPLICATIONS

This application claims the benefit of China Patent Application No. 202311367876.5, filed Oct. 20, 2023, the entirety of which is incorporated by reference herein.

### BACKGROUND OF THE DISCLOSURE

### Field of the Disclosure

The application relates in general to an electronic device, and in particular, to an electronic device having great flatness after splicing.

### Description of the Related Art

Display panels have been widely used in electronic devices such as mobile phones, televisions, monitors, tablet computers, automotive displays, wearable devices, and desktop computers. With the vigorous development of electronic products, the requirements for the display quality provided by such electronic products are increasing, so the electronic devices used for display are constantly improving towards providing display effects at higher resolutions.

### BRIEF SUMMARY OF DISCLOSURE

An embodiment of the disclosure provides an electronic device, including an electronic panel, a reinforcement plate, and at least three adjustment members. The reinforcement plate has a first surface and a second surface that are opposite to each other. The electronic panel is disposed on the first surface of the reinforcement plate, and the adjustment members are disposed on the second surface. The electronic panel has an upper surface. There is a distance between the bottom surface of each adjustment member and the upper surface. The difference between the distances is greater than or equal to 0 and less than or equal to 0.1 millimeters.

An embodiment of the disclosure also provides a splice electronic apparatus, including a supporting frame and a plurality of aforementioned electronic devices. The supporting frame has a supporting surface, and the electronic devices are disposed on the supporting surface in a spliced manner.

An embodiment of the disclosure further provides a manufacturing method of the electronic device. The method includes providing a carrier having a first area and a second area. The method includes disposing the electronic device on the first area, disposing at least three gauge blocks on the second area, and moving the plane of a jig toward the second surface to let the plane contact and press the at least three gauge blocks and the at least three adjustment members.

### BRIEF DESCRIPTION OF DRAWINGS

The disclosure can be more fully understood by reading the subsequent detailed description and examples with references made to the accompanying drawings, wherein:

FIG. 1A is a schematic diagram of an electronic device according to an embodiment of the disclosure;

FIG. 1B is a front view diagram of the electronic device according to an embodiment of the disclosure;

FIG. 1C is a partial enlarged diagram of the electronic device according to an embodiment of the disclosure;

FIG. 2 is a schematic diagram represents that the electronic device is disposed on a carrier according to an embodiment of the disclosure;

FIG. 3 is a schematic diagram represents that the electronic device moves to the position below the jig according to an embodiment of the disclosure;

FIG. 4 is a schematic diagram represents that the jig presses and contacts the gauge blocks and the protruding blocks of the electronic device according to an embodiment of the disclosure;

FIG. 5 is a partial enlarged diagram of FIG. 4;

FIG. 6 is a schematic diagram of a supporting frame according to an embodiment of the disclosure; and

FIG. 7 is a schematic diagram of a splice electronic apparatus according to an embodiment of the disclosure.

### DETAILED DESCRIPTION OF DISCLOSURE

The making and using of the embodiments of the electronic device and the splice electronic apparatus are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, areas, steps, operations and/or components would be pointed to existence, but not limited to the existence of one or a plurality of the corresponding features, areas, steps, operations and/or components.

In addition, in this specification, relative expressions are used. For example, “below” and “above” are used to describe the position of one element relative to another. It should be appreciated that if a device is flipped upside down, an element that is “below” will become an element that is “above”.

When the corresponding component (such as layer or area) is referred to “on another component (or the variant thereof)”, it may be directly on another component, or other component may exist between them. On the other hand, when the component is referred to “directly on another component (or the variant thereof)”, any component does not exist between them. Moreover, when a component is referred to “on another component (or the variant thereof)”, the component and the other component has a positional relationship in a top view direction, the component can be disposed above or below the other component, and the positional relationship is based on the orientation of the device.

In some embodiments of the disclosure, terms concerning attachments, coupling and the like, such as “connected”, refer to a relationship wherein structures are secured or attached to one another either directly or indirectly through intervening structures, unless expressly described otherwise.

It should be understood that, although the terms “first”, “second”, etc. can be used herein to describe various elements, layers and/or sections, these elements, layers and/or sections should not be limited by these terms. These terms are only used to distinguish one element layer or section from another element, layer or section. Thus, a first element, layer or section discussed below could be termed a second element, layer or section without departing from the teachings of the present disclosure. For brevity, the terms “first”, “second”, etc. may not be used in the specification. The first element and/or the second element in claims can refer to any element that meets the description in the specification without departing from the spirit and scope of the invention as defined by the appended claims.

The terms “about” and “substantially” typically mean +/−15% of the stated value, for example, +/−10%, +/−5%, +/−3%, +/−2%, +/−1%, or +/−0.5% of the stated value. The stated value of the present disclosure is an approximate value. When there is no specific description to the terms “about” and “substantially”, the stated value includes the meaning of “about” or “substantially”. Unless defined otherwise, all technical and scientific terms used herein have the same meaning as commonly understood by one of ordinary skill in the art to which this disclosure belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise. Moreover, for brevity, some elements can be suitably omitted in the figures.

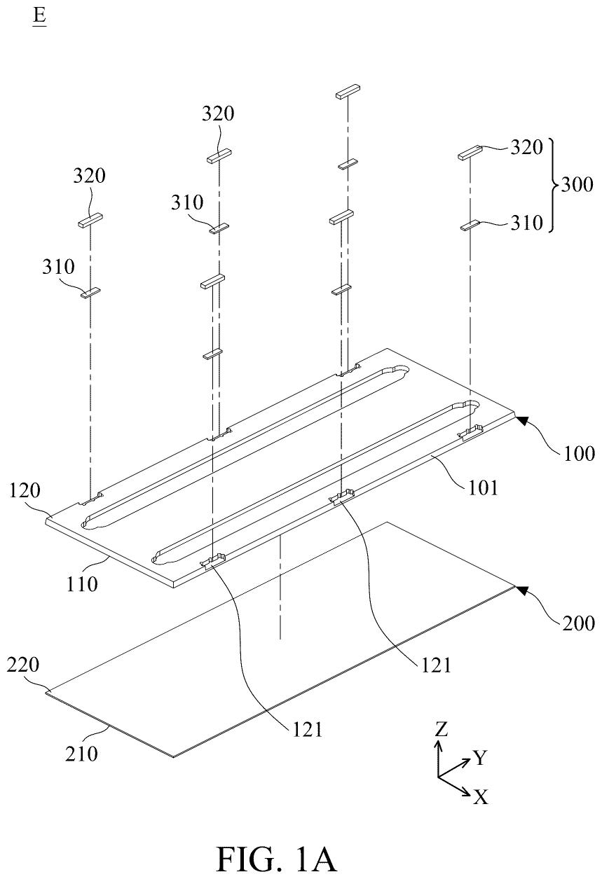

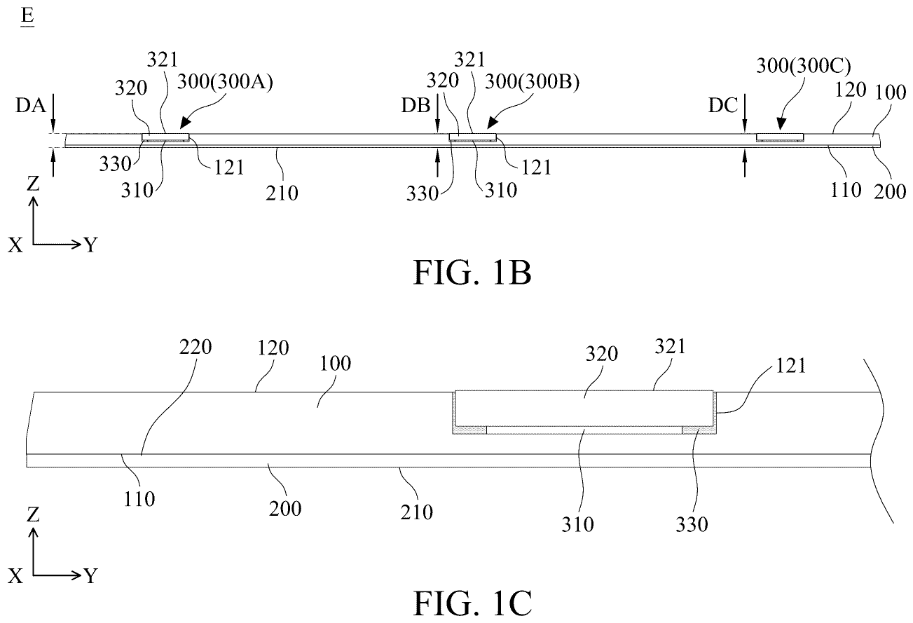

Referring to FIG. 1A, an electronic device E in an embodiment of the disclosure primarily includes a reinforcement plate 100, an electronic panel 200, and a plurality of adjustment members 300. For example, the electronic device E can include a display device, a backlight device, an antenna device, a sensing device, or the combination thereof, but it is not limited thereto. The display device can be a non-self-emitting type display device or a self-emitting type display device. The antenna device can be a liquid crystal type antenna device or a non-liquid crystal type antenna device. The sensing device can be a sensing device for sensing capacitance, light, heat, or ultrasonic, but it is not limited thereto. The electronic device can include a plurality of electronic elements, and the electronic elements can include a passive element and an active element, such as a capacitance, a resistance, an inductance, a diode, a transistor, or etc. The diode can include a light-emitting diode or a photoelectric diode. For example, the light-emitting diode can include an organic light-emitting diode (OLED), a mini LED, a micro LED, or a quantum dot LED, but it is not limited thereto.

The reinforcement plate 100 can include a material with sufficient stiffness (such as metal or plastic), and has a first surface 110 and a second surface 120 that are opposite to each other. The electronic panel 200 is disposed on the first surface 110, and an upper surface 210 of the electronic panel 200, that serves as the display surface thereof, faces away from the first surface 110. In this embodiment, the dimensions (the length, the width) of the reinforcement plate 100 are substantially the same as that of the electronic panel 200, so that the reinforcement plate 100 can fully support the electronic panel 200 from the lower surface 220 of the electronic panel 200.

The adjustment members 300 are disposed on the second surface 120 of the reinforcement plate 100. In particular, there are a plurality of accommodating slots 121 formed on the second surface 120 of the reinforcement plate 100, and the adjustment members 300 can be disposed in the accommodating slots 121 one-to-one. Each of the adjustment members 300 includes an elastic body 310 and a protruding block 320. The protruding block 320 is connected to the second surface 120 of the reinforcement plate 100 via the elastic body 310. Therefore, the elastic body 310 is disposed between the protruding block 320 and the second surface 120 of the reinforcement plate 100. The elastic body 310 is flexible, so that the protruding block 320 is enable to move relative the reinforcement plate 100 by the deformation of the elastic body 310. For example, the elastic body 310 can include a sponge or a spring, but it is not limited thereto.

In should be noted that, as shown in FIG. 1A to FIG. 1C, when the protruding block 320 of each of the adjustment members 300 is located at a desired position, an adhesive member 330 can be filled in the accommodating slots 121. The adhesive member 330 can be disposed between the protruding block 320 and the lateral wall of the accommodating slot 121 and contacts them, so as to adhere the protruding block 320 and the reinforcement plate 100. Thus, the position of the protruding block 320 can be affixed. At this time, a distance can be formed between the bottom surface 321 of the protruding block 320, that faces away from the reinforcement plate 100, and the upper surface 210 of the electronic panel 200. The difference between the aforementioned distances of each adjustment member 300 can be greater than or equal to 0 and less than or equal to 0.1 millimeters (mm), or greater than or equal to 0 and less than or equal to 0.05 millimeters. In detail, as shown in FIG. 1B, a distance DA is formed between the bottom surface 321 of the protruding block 320 of one adjustment members 300A and the upper surface 210 of the electronic panel 200, a distance DB is formed between the bottom surface 321 of the protruding block 320 of another one adjustment members 300B and the upper surface 210 of the electronic panel 200, and the difference between the distance DA and the distance DB is greater than or equal to 0 and less than or equal to 0.1 millimeters (or 0.05 millimeters). Moreover, a distance DC is formed between the bottom surface 321 of the protruding block 320 of another one adjustment members 300C and the upper surface 210 of the electronic panel 200, the difference between the distance DA and the distance DC is greater than or equal to 0 and less than or equal to 0.1 millimeters (or 0.05 millimeters), and the difference between the distance DB and the distance DC is greater than or equal to 0 and less than or equal to 0.1 millimeters (or 0.05 millimeters). In other words, the distances between the bottom surfaces 321 of the adjustment members 300 and the upper surface 210 of the electronic panel 200 are substantially the same, and the protruding blocks 320 protrude from the second surface 120 of the reinforcement plate 100.

Furthermore, it should be noted that, the electronic device E needs to include at least three adjustment members 300. When the number of the adjustment members 300 is three, the three adjustment members 300 should be prevented to dispose on the same straight line. In this embodiment, the accommodating slots 121 for accommodating the adjustment members 300 can be disposed along the edge 101 of the reinforcement plate 100, so that the adhesive members 330 can be facilitated to fill in the accommodating slots 121.

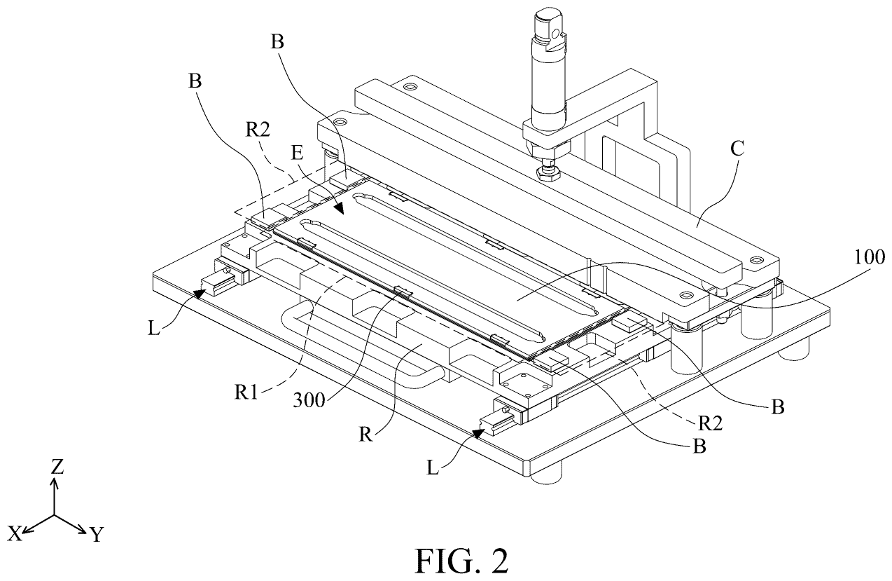

The manufacturing method of the aforementioned electronic device E is discussed below. As shown in FIG. 2, a carrier R can be provided. The carrier R includes a first area R1 and second areas R2, and the first area R1 is situated between the second areas R2. The electronic device E (the combination of the reinforcement plate 100, the electronic panel 200, and the adjustment members 300) can be disposed in the first area R1 of the carrier R, and at least three gauge blocks B can be disposed in the second areas R2. When the electronic device E is disposed on the carrier R, the electronic panel 200 is situated between the reinforcement plate 100 and the carrier R. That is, the adjustment members 300 are exposed from above.

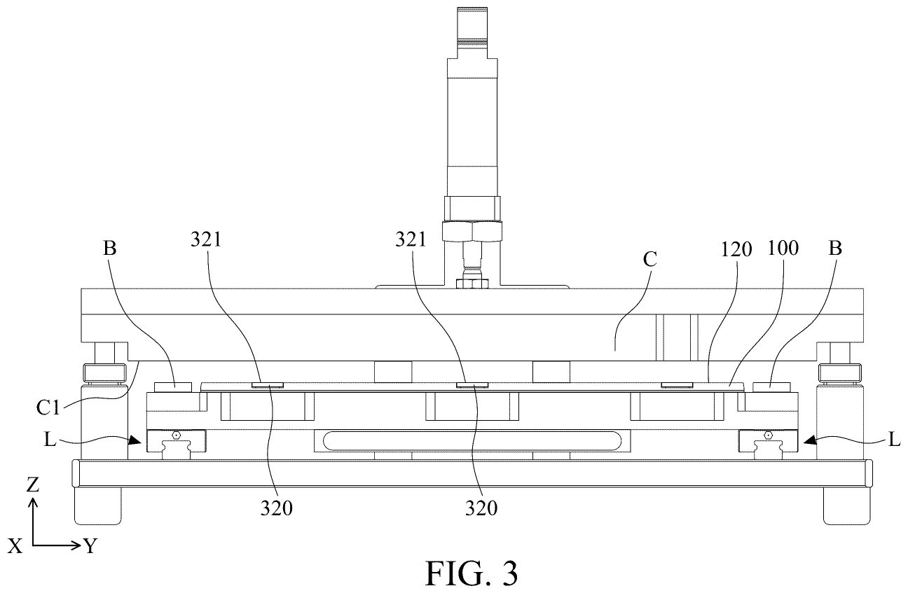

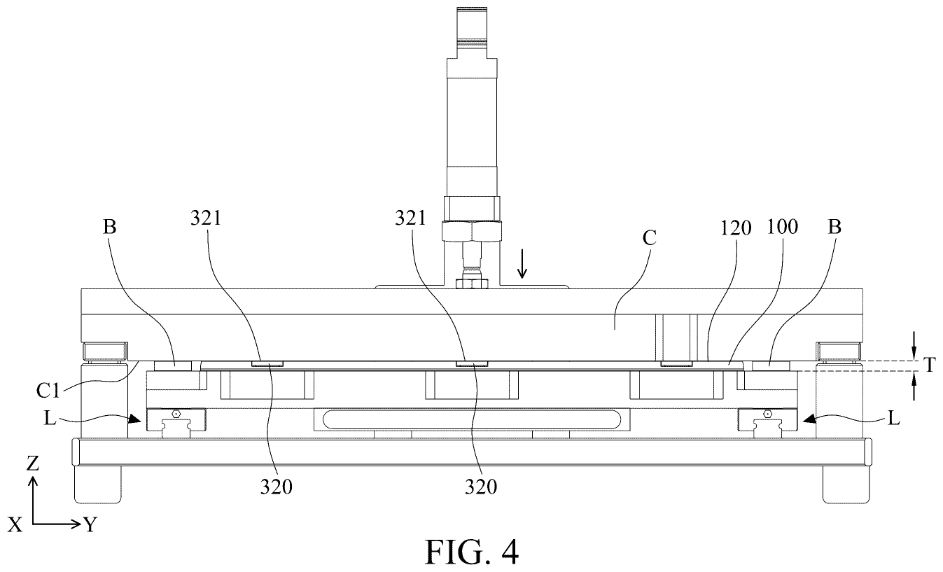

Next, as shown in FIG. 3 and FIG. 4, the carrier R can move along rails L to the position below a jig C, and the jig C can move toward the electronic device E. A plane C1 of the jig C that faces the electronic device E can move relative to the electronic device E toward its second surface 120, and can contact the bottom surfaces 321 of the protruding block 320 of the adjustment members 300 and press the protruding block 320. Since each of the elastic body 310 is flexible, and connects the protruding block 320 and the reinforcement plate 100 at the side opposite to the jig C, the elastic body 310 can be compressed and deformed when the protruding block 320 is pressed by the jig C, and the relative position between the protruding block 320 and the reinforcement plate 100 can be adjusted. When the plane C1 of the jig C contacts and presses the gauge blocks B, the jig C cannot deform the gauge blocks B. Thus, the jig C stops accordingly. Therefore, the protruding blocks 320 of the adjustment members 300 can be substantially adjusted to the same height. The distance between the bottom surface 231 of the protruding block 320 of each of the adjustment members 300 and the upper surface 210 of the electronic panel 200 is substantially the same as a thickness T of each gauge blocks B.

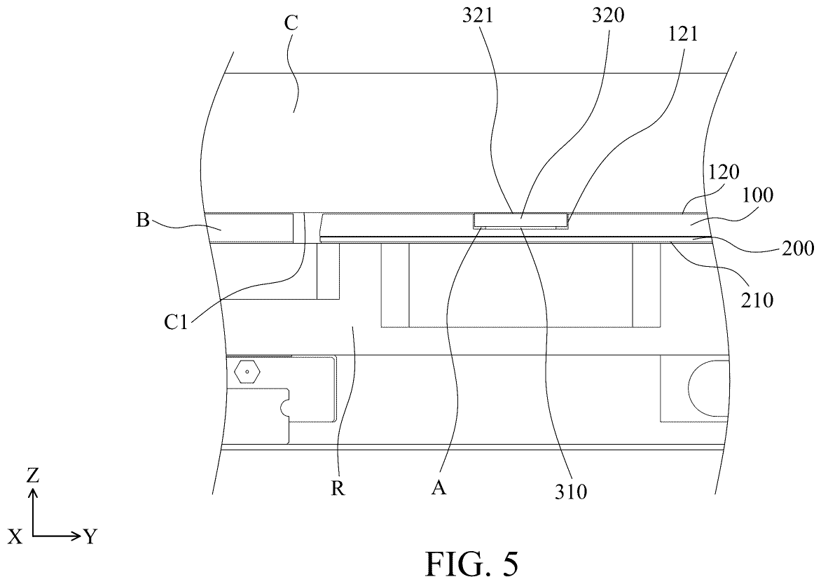

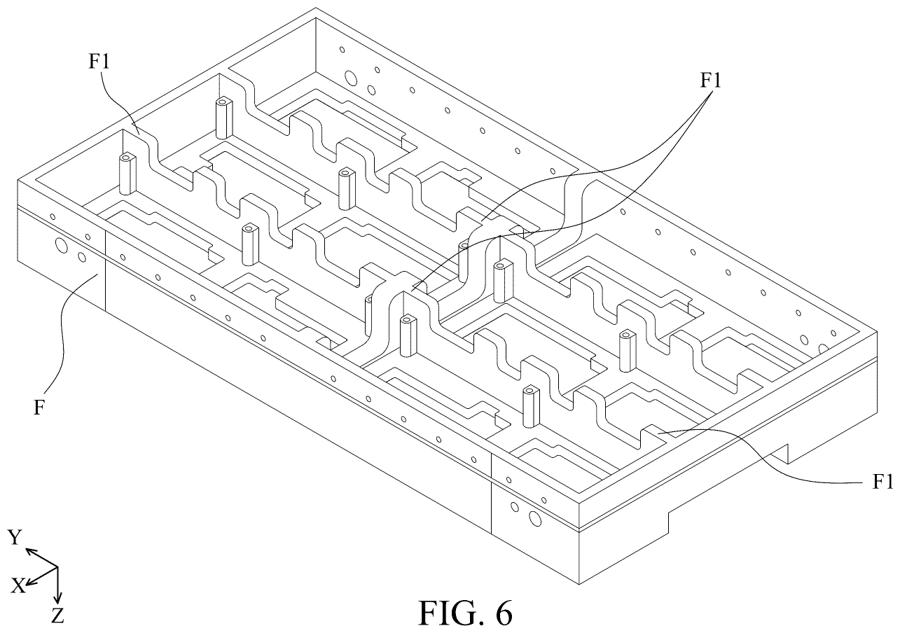

Subsequently, as shown in FIG. 5, after the step of moving the plane C1 of the jig C relative to the second surface 120, adhesive material A can be filled into the accommodating slots 121. In particular, the adhesive material A can be disposed between the protruding block 320 and the lateral wall of the accommodating slot 121 and contacts them. Finally, the adhesive material A can be cured to form the adhesive member 330, the adjustment member 300 can be affixed to the reinforcement plate 100, and the position of the protruding block 320 can be affixed by the adhesive member 330. For example, the adhesive material A can be light-curing glue, and the ultraviolet light can irradiate the adhesive material A to cure it, but it is not limited thereto. By using the aforementioned steps, the manufacture of the electronic device E in the disclosure can be completed.

In some embodiments, the adhesive material A can be applied between the adjustment members 300 and the reinforcement plate 100 before the plane C1 of the jig C moves relative to the second surface 120. In these embodiments, the step of curing the adhesive material A is still proceeded after the step of moving the plane C1 of the jig C relative to the second surface 120.

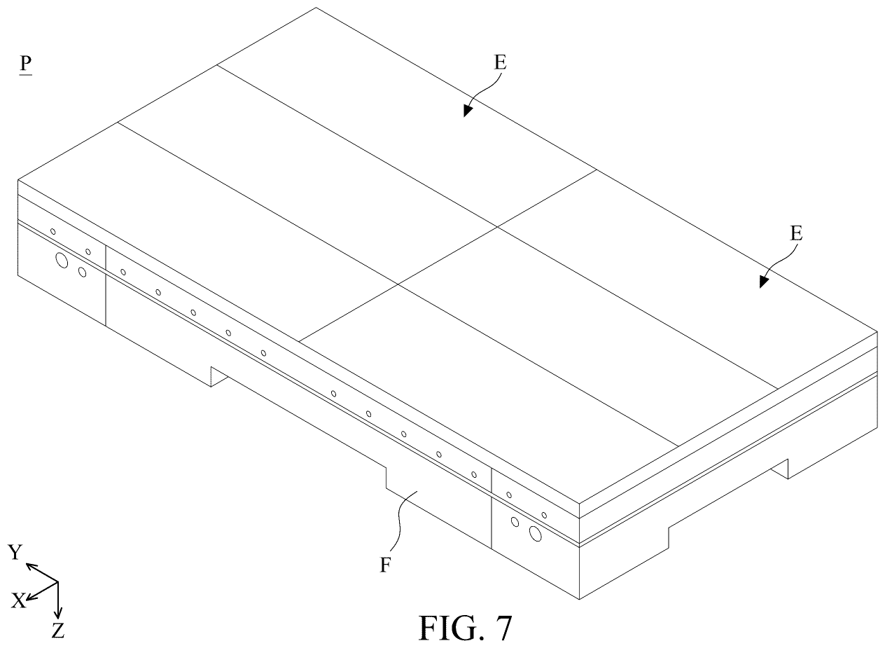

Referring to FIG. 6 and FIG. 7, when using multiple aforementioned electronic devices E to manufacture a splice electronic apparatus P, a supporting frame F can be provided firstly. The supporting frame F has a supporting surface F1 that is horizontal. Subsequently, a plurality of electronic devices E manufactured by the aforementioned manufacturing method can be provided, and the bottom surfaces 321 of the protruding blocks 320 in the electronic devices E can contact the supporting surface F1 of the supporting frame F. Because in each electronic devices E, the distances between the bottom surfaces 321 of the protruding blocks 320 and the upper surface 210 of the electronic panel 200 are substantially the same as the thickness of the gauge blocks B, the tolerance between the electronic devices E can be reduced, and the whole effect of the splice electronic apparatus P can be enhanced.

The features between the aforementioned embodiments can be used or combined as long as they do not violate or conflict the spirit of the present application.

In summary, an embodiment of the disclosure provides an electronic device, including an electronic panel, a reinforcement plate, and at least three adjustment members. The reinforcement plate has a first surface and a second surface that are opposite to each other. The electronic panel is disposed on the first surface of the reinforcement plate, and the adjustment members are disposed on the second surface. The electronic panel has an upper surface. There is a distance between the bottom surface of each adjustment member and the upper surface. The difference between the distances is greater than or equal to 0 and less than or equal to 0.1 millimeters.

An embodiment of the disclosure also provides a splice electronic apparatus, including a supporting frame and a plurality of aforementioned electronic devices. The supporting frame has a supporting surface, and the electronic devices are disposed on the supporting surface in a spliced manner.

An embodiment of the disclosure further provides a manufacturing method of the electronic device. The method includes providing a carrier having a first area and a second area. The method includes disposing the electronic device on the first area, disposing at least three gauge blocks on the second area, and moving a plane of a jig toward the second surface to let the plane contact and press the at least three gauge blocks and the at least three adjustment members.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the disclosure has been described by way of example and in terms of preferred embodiment, it should be understood that the disclosure is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An electronic device, comprising:
an electronic panel;
a reinforcement plate, having a first surface and a second surface that are opposite to each other, wherein the electronic panel is disposed on the first surface of the reinforcement plate; and
at least three adjustment members, disposed on the second surface, wherein the electronic panel has an upper surface, and there is a distance between a bottom surface of each of the at least three adjustment members and the upper surface, wherein a difference between the distances is greater than or equal to 0 and less than or equal to 0.1 millimeter.

2. The electronic device as claimed in claim 1, wherein the second surface has at least three accommodating slots, and the at least three adjustment members are respectively disposed in the at least three accommodating slots.

3. The electronic device as claimed in claim 2, wherein the reinforcement plate has an edge, and the at least three accommodating slots are disposed along the edge.

4. The electronic device as claimed in claim 2, wherein each of the at least three adjustment members comprises an elastic body and a protruding block, and the elastic body is disposed between the protruding block and the reinforcement plate.

5. The electronic device as claimed in claim 4, further comprising an adhesive member, disposed between the protruding block and a lateral wall of the accommodating slot.

6. The electronic device as claimed in claim 4, wherein the elastic body comprises a spring or a sponge.

7. The electronic device as claimed in claim 4, wherein the protruding blocks protrude from the second surface.

8. A splice electronic apparatus, comprising:
a supporting frame, having a supporting surface; and
a plurality of electronic devices, disposed on the supporting surface in a spliced manner, wherein each of the electronic devices comprises:
an electronic panel;
a reinforcement plate, having a first surface and a second surface that are opposite to each other, wherein the electronic panel is disposed on the first surface of the reinforcement plate; and
at least three adjustment members, disposed on the second surface, wherein the electronic panel has an upper surface, there is a distance between a bottom surface of each of the at least three adjustment members and the upper surface, wherein a difference between the distances is greater than or equal to 0 and less than or equal to 0.1 millimeters.

9. The splice electronic apparatus as claimed in claim 8, wherein the bottom surfaces of the at least three adjustment members are in contact with the supporting surface.

10. The splice electronic apparatus as claimed in claim 8, wherein the second surface has at least three accommodating slots, and the at least three adjustment members are respectively disposed in the at least three accommodating slots.

11. The splice electronic apparatus as claimed in claim 8, wherein the reinforcement plate has an edge, and the at least three accommodating slots are disposed along the edge.

12. The splice electronic apparatus as claimed in claim 8, wherein each of the at least three adjustment members comprises an elastic body and a protruding block, and the elastic body is disposed between the protruding block and the reinforcement plate.

13. The splice electronic apparatus as claimed in claim 12, further comprising an adhesive member, disposed between the protruding block and a lateral wall of the accommodating slot.

14. The splice electronic apparatus as claimed in claim 12, wherein the elastic body comprises a spring or a sponge.

15. The splice electronic apparatus as claimed in claim 12, wherein the protruding blocks protrude from the second surface.

16. A manufacturing method of an electronic device, comprising:
providing a carrier having a first area and a second area;
disposing an electronic device on the first area, wherein the electronic device includes a reinforcement plate, an electronic panel disposed on a first surface of the reinforcement plate, and at least three adjustment members disposed on a second surface of the reinforcement plate;
disposing at least three gauge blocks on the second area; and
moving a plane of a jig toward the second surface to let the plane contact and press the at least three gauge blocks and the at least three adjustment members.

17. The manufacturing method as claimed in claim 16, wherein before the step of moving the plane of the jig toward the second surface, the method further comprises:
applying an adhesive material between the at least three adjustment members and the reinforcement plate.

18. The manufacturing method as claimed in claim 17, wherein after the step of moving the plane of the jig toward the second surface, the method further comprises:
curing the adhesive material to affix the at least three adjustment members to the reinforcement plate.

19. The manufacturing method as claimed in claim 16, wherein after the step of moving the plane of the jig toward the second surface, the method further comprises:
applying an adhesive material between the at least three adjustment members and the reinforcement plate.

20. The manufacturing method as claimed in claim 19, wherein after the step of applying the adhesive material, the method further comprises:
curing the adhesive material to affix the at least three adjustment members to the reinforcement plate.
